(19) United States
(12) Patent Application Publication
(10) Pub. No.: US 2021/0193777 A1
(43) Pub. Date: Jun. 24, 2021

(54) DISPLAY SUBSTRATE AND DISPLAY DEVICE

(71) Applicants: Chengdu BOE Optoelectronics Technology Co., Ltd., Chengdu (CN); BOE Technology Group Co., Ltd., Beijing (CN)

(72) Inventors: Mengmeng Du, Beijing (CN); Xiangdan Dong, Beijing (CN); Hongwei Ma, Beijing (CN); Biao Liu, Beijing (CN); Jun Yan, Beijing (CN)

(73) Assignees: Chengdu BOE Optoelectronics Technology Co., Ltd.; BOE Technology Group Co., Ltd.

(21) Appl. No.: 17/004,450

(22) Filed: Aug. 27, 2020

(30) Foreign Application Priority Data
Dec. 20, 2019 (CN) 201911328075.1

(51) Int. Cl. H01L 27/32; H01L 23/00

(52) U.S. Cl. CPC H01L 27/3276; H01L 24/05; H01L 27/3248; H01L 27/323; H01L 2224/05566; H01L 2224/05018; H01L 2224/05573; H01L 2224/05558; H01L 2224/05572; H01L 2224/05083

(57) ABSTRACT

The present disclosure discloses a display substrate and a display device. The display substrate includes: a base substrate, including a display area and a bonding area located on at least one side of the display area, wherein the bonding area includes terminal areas and spacing areas between any two adjacent terminal areas among the terminal areas; connection terminals arranged in the terminal areas; a first inorganic insulating layer located on a side, where the connection terminals are arranged, of the base substrate; and a first organic insulating layer disposed between the base substrate and the first inorganic insulating layer and surrounding the bonding area.

The present application claims the priority from Chinese Patent Application No. 201911328075.1, filed with the Chinese Patent Office on Dec. 20, 2019, and entitled “DISPLAY SUBSTRATE AND DISPLAY DEVICE”, which is hereby incorporated by reference in its entirety.

### FIELD

The present disclosure relates to the technical field of display, and particularly to a display substrate and a display device.

### BACKGROUND

In the manufacturing process of an organic light-emitting diode (OLED) touch screen, after the backplane manufacturing process, the evaporation and encapsulation process of a light emitting device will be performed, and then a metal electrode layer of a touch structure is manufactured. Generally, an organic film layer is arranged in the bonding area of the backplane to protect connection terminals, and there is no film layer structure such as a light emitting material layer and an encapsulation layer on the organic film layer.

### SUMMARY

The present disclosure discloses a display substrate and a display device. A display substrate includes: a base substrate; connection terminals; a first inorganic insulating layer; and a first organic insulating layer;

wherein the base substrate includes a display area and a bonding area located on at least one side of the display area, and the bonding area includes terminal areas and spacing areas between any two adjacent terminal areas among the terminal areas;

wherein the connection terminals are arranged in the terminal areas;

the first inorganic insulating layer is located on a side, where the connection terminals are arranged, of the base substrate; the first inorganic insulating layer covers the bonding area and is provided with first openings corresponding to the connection terminals in one-to-one correspondence; and an orthographic projection, on the base substrate, of each first opening is within an orthographic projection, on the base substrate, of a connection terminal corresponding to the each first opening; and

the first organic insulating layer is disposed between the base substrate and the first inorganic insulating layer and surrounding the bonding area, wherein the first organic insulating layer does not overlap with the bonding area.

Optionally, each connection terminal includes a first electrical connection structure and a second electrical connection structure sequentially stacked on the base substrate;

the first inorganic insulating layer is disposed between the first electrical connection structure and the second electrical connection structure; and the first electrical connection structure and the second electrical connection structure are connected via a first opening corresponding to the each connection terminal.

Optionally, the display substrate further includes a plurality of sub-pixels located in the display area; at least one of the plurality of sub-pixels includes a thin film transistor and a planarization layer; the thin film transistor includes source-drain electrodes, and the planarization layer is located on a side, away from the base substrate, of the thin film transistor; the first electrical connection structure and the source-drain electrodes are in a same layer; and the first organic insulating layer includes the planarization layer.

Optionally, the source-drain electrodes include a source-drain electrode layer and a connection electrode layer that are stacked; and

the first electrical connection structure includes a first part which is in a same layer with the source-drain electrode layer and a second part which is in a same layer with the connection electrode layer.

Optionally, the display substrate further includes a touch electrode structure located in the display area; wherein the touch electrode structure includes a first electrode and a second electrode which are sequentially arranged on a base substrate; and

the second electrical connection structure and the second electrode are in a same layer.

Optionally, the first inorganic insulating layer includes a buffer layer and a first interlayer insulating layer sequentially stacked on the base substrate,

wherein the buffer layer is located on a side, facing the base substrate, of the touch electrode structure; and

the first interlayer insulating layer is located between the first electrode and the second electrode of the touch electrode structure.

Optionally, the thin film transistor further includes a gate electrode; wherein the gate electrode is located on a side, facing the base substrate, of the source-drain electrodes;

the each connection terminal further includes a third electrical connection structure stacked with the first electrical connection structure and the second electrical connection structure; and the third electrical connection structure and the gate electrode are in a same layer.

Optionally, the display substrate further includes:

a second inorganic insulating layer located between the gate electrode and the source-drain electrodes, wherein the second inorganic insulating layer covers the bonding area and is provided with second openings corresponding to the connection terminals in one-to-one correspondence;

an orthographic projection, on the base substrate, of each second opening is within an orthographic projection, on the base substrate, of a connection terminal corresponding to the each second opening; and

the first electrical connection structure and the third electrical connection structure are connected via a second opening corresponding to the each connection terminal.

Optionally, the second inorganic insulating layer includes a gate insulating layer and a second interlayer insulating layer sequentially stacked on the base substrate.

Optionally, the base substrate includes two or more bonding areas.

Optionally, at least one of the bonding areas is a flexible circuit board bonding area or a chip bonding area.

A display device includes the display substrate according any one of the above.

### BRIEF DESCRIPTION OF THE DRAWINGS

FIG. 1 is a schematic structural diagram of a display substrate according to an embodiment of the present disclosure.

FIG. 2 is a schematic cross-sectional view of the display substrate in FIG. 1 along the direction A1-A2.

FIG. 3 is a schematic cross-sectional view of the display substrate in FIG. 1 along the direction B1-B2.

### DETAILED DESCRIPTION OF THE EMBODIMENTS

The technical solutions in the embodiments of the present disclosure will be described clearly and completely with reference to the drawings in the embodiments of the present disclosure. Obviously, the described embodiments are only a part of the embodiments of the present disclosure, but not all the embodiments. On the basis of the embodiments of the present disclosure, all other embodiments obtained by a person of ordinary skill in the art without making creative efforts fall within the protection scope of the present disclosure.

Before a touch structure is manufactured, an inorganic buffer layer is manufactured to separate the touch structure from the light emitting material layer and the encapsulation layer, so as to avoid interference, and the inorganic buffer layer covers the bonding area. Due to the poor adhesion between the inorganic buffer layer and the organic layer, when the module bonding is squeezed, it is prone to peeling of the organic layer, resulting in a poor display panel.

As shown in FIGS. 1 to 3, an embodiment of the present disclosure provides a display substrate, including: a base substrate 1, a first inorganic insulating layer 3 and a first organic insulating layer 4;

wherein base substrate 1 includes a display area 11 and a bonding area 12 located on at least one side of the display area 11, and the bonding area 12 includes terminal areas 122 and spacing areas 121 between any two adjacent terminal areas among the terminal areas 122;

wherein connection terminals 2 are located on the base substrate 1 and arranged in the terminal areas 122;

the first inorganic insulating layer 3 is located on a side, where the connection terminals are arranged, of the base substrate 1; the first inorganic insulating layer 3 covers the bonding area 12 and is provided with first openings corresponding to the connection terminals 2 in one-to-one correspondence; and an orthographic projection, on the base substrate 1, of each first opening is within an orthographic projection, on the base substrate 1, of a connection terminal 2 corresponding to the each first opening; and

the first organic insulating layer 4 is disposed between the base substrate 1 and the first inorganic insulating layer 3 and surrounding the bonding area 12, wherein the first organic insulating layer 4 does not overlap with the bonding area 12.

The above display substrate includes the first organic insulating layer 4 and the first inorganic insulating layer 3; wherein the first inorganic insulating layer 3 covers the bonding area 12 and is provided with the first openings exposing the connection terminals 2; an orthographic projection of the first opening is within an orthographic projection of the connection terminal 2, that is, the pattern of the first inorganic insulating layer 3 covers edges of the connection terminals 2, which can prevent the edges of the connection terminals 2 from being corroded; the first organic insulating layer 4 does not overlap with the bonding area 12, that is, the first organic insulating layer 4 is not arranged in the bonding area 12, and further the first inorganic insulating layer 3 is not contacted with the first organic insulating layer 4 in the bonding area 12, so that the problem of peeling of the first organic insulating layer 4 and the first inorganic insulating layer 3 will not occur when a force is applied in the module bonding process. Therefore, the poor structure of the film layer in the bonding area 12 of the display substrate can be avoided, and the overall yield of the display substrate can be improved.

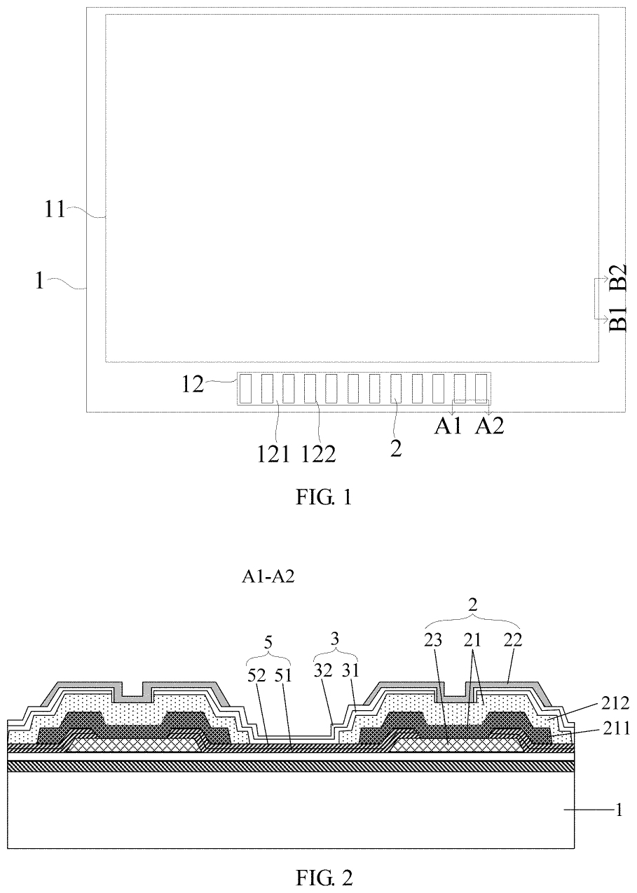

In some embodiments, the connection terminal may include two or more layers of electrical connection structures. Specifically, as shown in FIG. 2, the connection terminal 2 includes a first electrical connection structure 21 and a second electrical connection structure 22 sequentially stacked on the base substrate 1.

Specifically, as shown in FIG. 2, the first inorganic insulating layer 3 is disposed between the first electrical connection structure 21 and the second electrical connection structure 22; and the first electrical connection structure 21 and the second electrical connection structure 22 are connected via a first opening corresponding to the connection terminal 2 arranged in the first inorganic insulating layer 3.

Specifically, as shown in FIG. 2, the second electrical connection structure 22 is a top layer structure of the connection terminal 2 and serves as a bonding contact layer of the connection terminal 2.

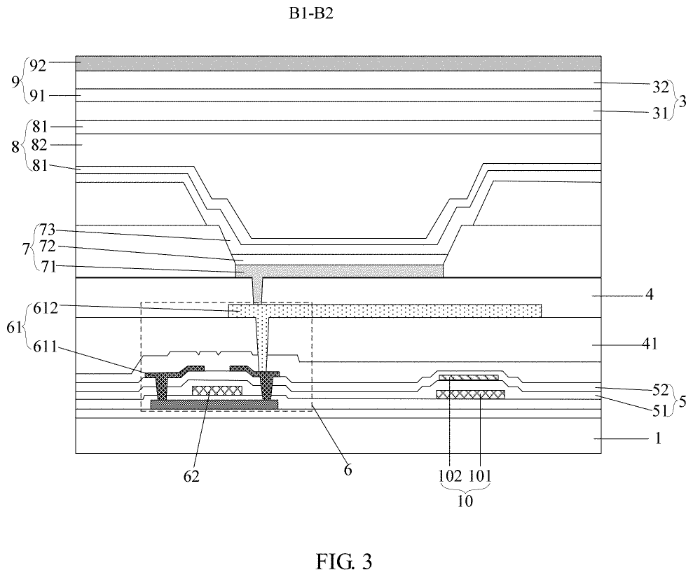

In some embodiments, as shown in FIG. 3, the display substrate according to an embodiment of the present disclosure further includes a plurality of sub-pixels located in the display area; at least one of the plurality of sub-pixels includes a thin film transistor (TFT) 6 and a planarization layer; the thin film transistor 6 includes source-drain electrodes 61, and the planarization layer is located on a side, away from the base substrate 1, of the thin film transistor 6.

Specifically, the first electrical connection structure 21 and the source-drain electrodes 61 may be in a same layer structure. The ‘same layer structure’ does not mean at the same level, but may be formed in the same layer in the preparation process, for example, may be simultaneously formed through a patterning process by using the same layer or layers of material, thereby simplifying the preparation process.

Exemplarily, as shown in FIGS. 2 and 3, the source-drain electrodes 61 may include a source-drain layer 611 and a connection electrode layer 612 that are stacked; correspondingly, the first electrical connection structure 21 may include a first part 211 which is in a same layer with the source-drain electrode layer 611 and a second part 212 which is in a same layer with the connection electrode layer 612.

Specifically, the first organic insulating layer includes the above planarization layer.

In some embodiments, as shown in FIG. 3, the first organic insulating layer 4 is configured as the above planarization layer, that is, the first organic insulating layer 4 covers the thin film transistor 6 in the display area 11 to provide a planarization surface on the side, away from the base substrate 1, of the thin film transistor 6.

Specifically, the material of the first organic insulating layer may include an inorganic insulating material such as silicon oxide, silicon nitride, silicon oxynitride and so on, and may also include an organic insulating material such as polyimide, polyphthalimide, polyamide, acrylic resin, benzocyclobutene, or phenol resin and so on, which is not limited in the embodiments of the present disclosure.

Optionally, the first organic insulating layer may also include other organic film layers disposed between the base substrate and the first inorganic insulating layer. The first organic insulating layer does not overlap with the bonding area, that is, none of the organic film layers between the base substrate and the first inorganic insulating layer overlaps with the bonding area.

As shown in FIG. 3, in some embodiments, the display substrate further includes another planarization layer 41 between the source-drain layer 611 and the connection electrode layer 612. Specifically, the planarization layer 41 may be located only in the display area. Optionally, the first organic insulating layer may include the planarization layer; or, the first organic insulating layer may not include the planarization layer.

In some embodiments, as shown in FIG. 3, the display substrate according to an embodiment of the present disclosure may further include a light emitting device 7 located on a side, facing away from the base substrate 1, of the thin film transistor 6, and an encapsulation layer 8 located on a side, facing away from the base substrate 1, of the light emitting device 7. Specifically, the light emitting device 7 includes a third electrode 71, a light emitting function layer 72, and a fourth electrode 73 which are sequentially arranged. The third electrode 71 is arranged on the first organic insulating layer 4 and is electrically connected to the source-drain electrodes 61 through a via hole of the first organic insulating layer 4. The encapsulation layer 8 is used to encapsulate the light emitting device 7, and may specifically include two inorganic layers 81 and an organic layer 82 between the two inorganic layers 81.

Specifically, the first inorganic insulating layer 3 is located on a side, facing away from the base substrate 1, of the encapsulation layer 8.

In some embodiments, as shown in FIG. 3, the display substrate according to an embodiment of the present disclosure may further include a touch electrode structure 9 located in the display area; and the touch electrode structure 9 includes a first electrode 91 and a second electrode 92 which are sequentially arranged on the base substrate 1.

Specifically, the touch electrode structure 9 is located on a side, facing away from the base substrate 1, of the encapsulation layer 8.

Specifically, as shown in FIGS. 2 and 3, the second electrical connection structure 22 of the connection terminal 2 and the second electrode 92 may be in a same layer.

In some embodiments, as shown in FIGS. 2 and 3, the first inorganic insulating layer 3 may include a buffer layer 31 and a first interlayer insulating layer 32 sequentially stacked on the base substrate 1, wherein the buffer layer 31 is located on a side, facing the base substrate 1, of the touch electrode structure 9, i.e., between the touch electrode structure 9 and the encapsulation layer 8; and the first interlayer insulating layer 32 is located between the first electrode 91 and the second electrode 92 of the touch electrode structure 9.

Optionally, the first inorganic insulating layer 3 may also include only the buffer layer 31, or only the first interlayer insulating layer 32.

In some embodiments, as shown in FIG. 3, in the display substrate according to an embodiment of the present disclosure, the thin film transistor 6 further includes a gate electrode 62; and the gate electrode 62 is located at a side, facing the base substrate 1, of the source-drain electrodes 61.

Specifically, as shown in FIGS. 2 and 3, the connection terminal 2 may further include a third electrical connection structure 23 stacked with the first electrical connection structure 21 and the second electrical connection structure 22; and the third electrical connection structure 23 and the gate electrode 62 may be in a same layer structure.

Further, as shown in FIG. 3, the display substrate according to an embodiment of the present disclosure further includes a second inorganic insulating layer 5, wherein the second inorganic insulating layer 5 is located between the gate electrode 62 and the source-drain electrodes 61.

Specifically, as shown in FIG. 2, the second inorganic insulating layer 5 covers the bonding area, and is provided with second openings corresponding to the connection terminals 2 in one-to-one correspondence; an orthographic projection, on the base substrate 1, of each second opening is within an orthographic projection, on the base substrate 1, of the connection terminal 2 corresponding to the each second opening; and the first electrical connection structure 21 and the third electrical connection structure 23 are connected via a second opening corresponding to the connection terminal 2. At this time, the pattern of the second inorganic insulating layer 5 covers edges of the third electrical connection structures 23, which can prevent the edges of the connection terminals 2 from being corroded. The first inorganic insulating layer 3 overlaps with the second inorganic insulating layer 5 in the bonding area, and there is no organic film layer between the first inorganic insulating layer 3 and the second inorganic insulating layer 5, so that the problem of peeling of the organic film layer and the inorganic film layer will not occur in the module bonding process. Therefore, the poor structure of the film layer in the bonding area of the display substrate can be avoided, and the overall yield of the display substrate can be improved.

Specifically, as shown in FIGS. 2 and 3, the second inorganic insulating layer 5 may include a gate insulating layer 51 and a second interlayer insulating layer 52 sequentially stacked on the base substrate 1.

As shown in FIG. 3, the display substrate includes a storage capacitor 10, and the storage capacitor 10 may include a first capacitor electrode 101 and a second capacitor electrode 102. Optionally, the gate insulating layer 51 is arranged between the first capacitor electrode 101 and the second capacitor electrode 102, and the second interlayer insulating layer 52 is arranged between the second capacitor electrode 102 and the source-drain electrodes 61 of the thin film transistor 6.

Optionally, the second inorganic insulating layer 5 may also include only the gate insulating layer 51, or only the second interlayer insulating layer 52.

In some embodiments, in the display substrate according to an embodiment of the present disclosure, the bonding area of the base substrate may be a flexible circuit board bonding area or a chip bonding area.

Specifically, in the display substrate according to an embodiment of the present disclosure, the base substrate may include two or more bonding areas. For example, there may be one flexible circuit board bonding area and one chip bonding area.

In addition, an embodiment of the present disclosure further provides a display device, including the display substrate according any one of the above.

Specifically, in the module bonding process of the display device, the problem of peeling of the organic film layer and the inorganic film layer will not occur when a force is applied. Therefore, the poor structure of the film layer in the bonding area of the display substrate can be avoided, and the overall yield of the display substrate can be improved.

Specifically, the display device is an OLED touch display device, which can be applied to various products such as smart phones, tablet computers, and displays.

Obviously, those skilled in the art can make various modifications and variations to the embodiments of the present disclosure without departing from the spirit and scope of the present disclosure. In this way, if these modifications and variations of the present disclosure fall within the scope of the claims of the present disclosure and their equivalent art, the present disclosure also intends to include these modifications and variations.

What is claimed is:

1. A display substrate, comprising:
a base substrate;
connection terminals;
a first inorganic insulating layer; and
a first organic insulating layer;
wherein the base substrate comprises:
a display area; and
a bonding area arranged on at least one side of the display area,
wherein the bonding area comprises:
terminal areas; and
spacing areas between any two adjacent terminal areas among the terminal areas;
wherein the connection terminals are arranged in the terminal areas;
wherein the first inorganic insulating layer is arranged on a side, where the connection terminals are arranged, of the base substrate;
the first inorganic insulating layer covers the bonding area and is provided with first openings corresponding to the connection terminals in one-to-one correspondence; and
an orthographic projection, on the base substrate, of each first opening is within an orthographic projection, on the base substrate, of a connection terminal corresponding to the each first opening; and
wherein the first organic insulating layer is disposed between the base substrate and the first inorganic insulating layer and surrounding the bonding area; and
the first organic insulating layer does not overlap with the bonding area.

2. The display substrate according to claim 1, wherein each connection terminal comprises a first electrical connection structure and a second electrical connection structure sequentially stacked on the base substrate;
the first inorganic insulating layer is disposed between the first electrical connection structure and the second electrical connection structure; and
the first electrical connection structure and the second electrical connection structure are connected via a first opening corresponding to the each connection terminal.

3. The display substrate according to claim 2, further comprising:
a plurality of sub-pixels arranged in the display area;
wherein at least one of the plurality of sub-pixels comprises a thin film transistor and a planarization layer;
wherein the thin film transistor comprises source-drain electrodes; and
the planarization layer is arranged on a side, away from the base substrate, of the thin film transistor;
wherein the first electrical connection structure and the source-drain electrodes are in a same layer; and
the first organic insulating layer comprises the planarization layer.

4. The display substrate according to claim 3, wherein the source-drain electrodes comprise a source-drain electrode layer and a connection electrode layer that are stacked; and
the first electrical connection structure comprises a first part which is in a same layer with the source-drain electrode layer and a second part which is in a same layer with the connection electrode layer.

5. The display substrate according to claim 3, further comprising:
a touch electrode structure arranged in the display area;
wherein the touch electrode structure comprises a first electrode and a second electrode which are sequentially arranged on a side, away from the base substrate, of the planarization layer; and
the second electrical connection structure and the second electrode are in a same layer.

6. The display substrate according to claim 5, wherein the first inorganic insulating layer comprises a buffer layer and a first interlayer insulating layer sequentially stacked on the base substrate,
wherein the buffer layer is arranged on a side, facing the base substrate, of the touch electrode structure; and
the first interlayer insulating layer is arranged between the first electrode and the second electrode of the touch electrode structure.

7. The display substrate according to claim 6, wherein the thin film transistor further comprises a gate electrode;
wherein the gate electrode is arranged on a side, facing the base substrate, of the source-drain electrodes;
the each connection terminal further comprises a third electrical connection structure stacked with the first electrical connection structure and the second electrical connection structure; and
the third electrical connection structure and the gate electrode are in a same layer.

8. The display substrate according to claim 7, further comprising:
a second inorganic insulating layer arranged between the gate electrode and the source-drain electrodes;
wherein the second inorganic insulating layer covers the bonding area and is provided with second openings corresponding to the connection terminals in one-to-one correspondence;
an orthographic projection, on the base substrate, of each second opening is within an orthographic projection, on the base substrate, of a connection terminal corresponding to the each second opening; and
the first electrical connection structure and the third electrical connection structure are connected via a second opening corresponding to the each connection terminal.

9. The display substrate according to claim 8, wherein the second inorganic insulating layer comprises a gate insulating layer and a second interlayer insulating layer sequentially stacked on the base substrate.

10. The display substrate according to claim 1, wherein the base substrate comprises two or more bonding areas.

11. The display substrate according to claim 1, wherein at least one of the bonding areas is a flexible circuit board bonding area or a chip bonding area.

12. A display device, comprising the display substrate according to claim 1.
